(19) United States
(12) Patent Application Publication
(10) Pub. No.: US 2004/0061157 A1
(43) Pub. Date: Apr. 1, 2004

(54) Semiconductor device

(76) Inventors: Masahiro Kiyotoshi, Sagamihara-shi (JP); Kumi Okuwada, Kawasaki-shi (JP)

Correspondence Address: Finnegan, Henderson, Farabow,, Garrett & Dunner, L.L.P., 1300 I Street, N.W., Washington, DC, 20005-3315, US

(21) Appl. No.: 10/303,846

(22) Filed: Nov. 26, 2002

(30) Foreign Application Priority Data
Sep. 27, 2002 (JP) 2002-283523

(51) Int. Cl. H01L 27/108; H01L 29/76; H01L 21/336; H01L 31/119

(52) U.S. Cl. 257/296; 257/310

(57) ABSTRACT

Disclosed is a semiconductor device, comprising a semiconductor substrate, and a capacitor provided above the semiconductor substrate and comprising a lower electrode having a metallic property, an upper electrode having a metallic property and a dielectric region provided between the lower electrode and the upper electrode, the dielectric region including a first dielectric film containing silicon, oxygen and at least one element selected from hafnium and zirconium.

### CROSS-REFERENCE TO RELATED APPLICATIONS

This application is based upon and claims the benefit of priority from the prior Japanese Patent Application No. 2002-283523, filed Sep. 27, 2002, the entire contents of which are incorporated herein by reference.

### BACKGROUND OF THE INVENTION

1. Field of the Invention

The present invention relates to a semiconductor device and, in particular, to a semiconductor device having a capacitor.

2. Description of the Related Art

In recent years, studies have been made on an LSI with an analog circuit, such as an RF circuit, and a logic circuit, such as a CMOS circuit, integrated in the same chip. Such an analog circuit and logic circuit include not only transistors but also capacitors. It is necessary that, in order to integrate the analogue circuit and the logic circuit in the same chip, the capacitor characteristics satisfy requirements of these circuits simultaneously. For this requirement, proposals have been made on an MIM (Metal-Insulator-Metal) capacitor with a dielectric film sandwiched between metal electrodes. The MIM capacitor has an advantage of, for example, obtaining a high Q value, because of the use of a metal electrode, in comparison with a capacitor using a semiconductor, such as polysilicon, as an electrode material. By using a material of a higher dielectric constant than SiO₂ and SiN, as a dielectric film, it is possible to enhance the electric capacitance.

Jpn. Pat. Appln. KOKAI Publication No. 2000-183289 discloses, as the conventional technique, a structure in which a plurality of dielectric films are provided as a dielectric region of a capacitor. This KOKAI PUBLICATION discloses a ZrO₂ film, a Ta₂O₅ film, etc., as a dielectric film.

Jpn. Pat. Appln. KOKAI Publication No. 2000-208720 discloses a capacitor with a diffusion barrier provided between an electrode and a dielectric film. This KOKAI PUBLICATION discloses a structure in which a titanium nitride, etc., is used as an electrode, a tantalum oxide, a zirconium oxide, etc., are used as a dielectric film, and a zirconium nitride, a zirconium carbide, etc., are used as a diffusion barrier layer.

Jpn. Pat. Appln. KOKAI Publication No. 2001-267566 discloses a multi-layered dielectric stack having a plurality of dielectric films. This KOKAI PUBLICATION discloses a ZrO₂ film, an HfO₂ film, a Ta₂O₅ film, etc., as a dielectric film.

In the case where the ZrO₂ film, the HfO₂ film or the Ta₂O₅ film is used as the dielectric film, there occur a greater leakage current as well as a greater variation in electric capacitance, thus presenting problems as will be set out below.

As the electrode of the MIM capacitor for instance, use is often made of a metal nitride film, such as a TiN film and a WN film, which is excellent in diffusion barrier and smooth plane. If, however, the metal nitride film is used as the electrode, the oxidation reaction of the metal nitride film tends to occur at an interface between the Ta₂O₅ film (dielectric film) and the metal nitride film (electrode). As a result, oxygen deficiency occurs in the dielectric film, thus producing a cause for a larger leakage current. The reaction at this interface, though being to a negligible extent at a time of forming a film, is accelerated at a subsequent heating step. There occurs a greater problem in securing the high temperature operation of a device.

Further, in the case where a ZrO₂ film or an HfO₂ film is used as the dielectric film, it is possible to suppress the leakage current. Since, however, the voltage dependence and temperature dependence of the electric capacitance are high, a problem may be produced due to a greater variation in the electric capacitance.

In this way, a problem occurs such as involving a greater leakage current and a greater variation in the electric capacitance. It has, therefore, been difficult to obtain a semiconductor device having a capacitor excellent in characteristics and in reliability.

### BRIEF SUMMARY OF THE INVENTION

According to an aspect of the present invention, there is provided a semiconductor device, comprising: a semiconductor substrate; and a capacitor provided above the semiconductor substrate and comprising a lower electrode having a metallic property, an upper electrode having a metallic property and a dielectric region provided between the lower electrode and the upper electrode, the dielectric region including a first dielectric film containing silicon, oxygen and at least one element selected from hafnium and zirconium.

### BRIEF DESCRIPTION OF THE SEVERAL VIEWS OF THE DRAWING

FIG. 1 is a cross-sectional view showing a model of a whole schematic structure of a semiconductor device according to an embodiment of the present invention;

FIGS. 2A to 2D are cross-sectional views showing a model of a schematic form of a capacitor shown in FIG. 1;

FIGS. 3A to 3E are cross-sectional views showing, as a model, a manufacturing process of a semiconductor device according to first and second embodiments of the present invention; and

FIGS. 4A to 4E are cross-sectional views showing, as a model, a manufacturing process of a semiconductor device according to a third embodiment of the present invention.

### DETAILED DESCRIPTION OF THE INVENTION

The embodiments of the invention will be described below with reference to the accompanying drawing.

(Basic Structure)

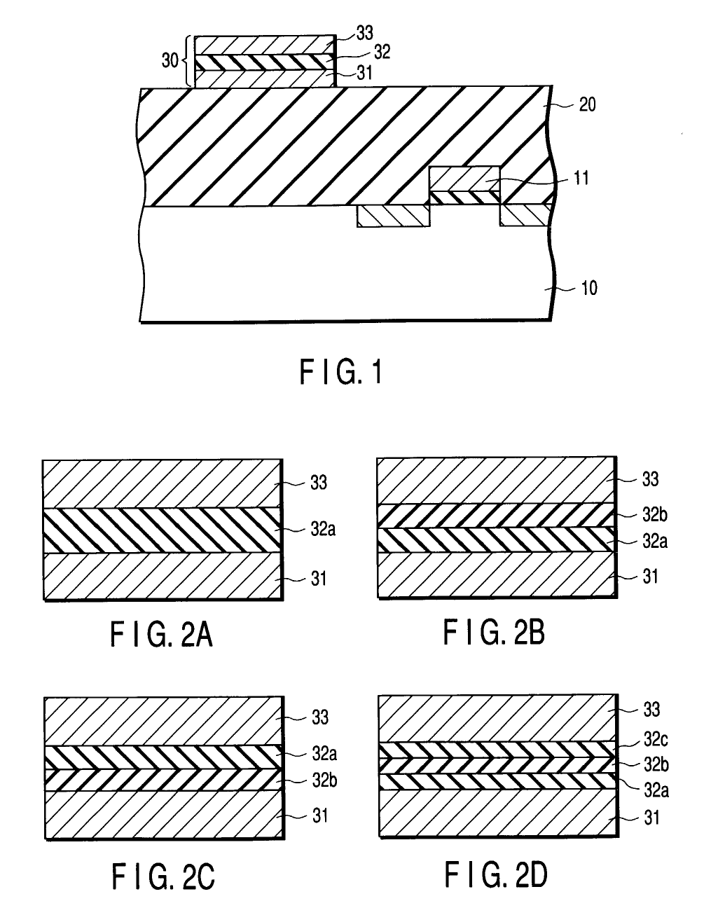

With reference to FIGS. 1 and 2A to 2D an explanation will be given below about the basic arrangement of a semiconductor device according to an embodiment of the present invention.

FIG. 1 is a cross-sectional view showing a model of a whole structure of a semiconductor device according to the embodiment of the present invention.

A semiconductor device shown in FIG. 1 comprises a semiconductor substrate 10, an intermediate area 20 provided on the semiconductor substrate 10 and a capacitor 30 provided on the intermediate area 20. As the semiconductor substrate 10 use is made of, for example, a silicon substrate and an active element, such as an MIS transistor 11, is provided on the surface of the semiconductor substrate 10. The intermediate area 20 includes not only an interlayer insulating film but also a wiring, a plug, etc. The capacitor 30 comprises a lower electrode 31, a dielectric region 32 provided on the lower electrode 31 and an upper electrode 33 provided on the dielectric region 32.

FIGS. 2A to 2D, each, is a cross-sectional view showing a model of a structural form of a capacitor 30 shown in FIG. 1.

As an example shown in FIG. 2A, the dielectric region 32 comprises a dielectric film (first dielectric film) 32a containing silicon, oxygen and at least one element selected from hafnium (Hf) and zirconium (Zr). Lower and upper surfaces of the dielectric film 32a are contacted with lower and upper electrodes 31 and 33, respectively. Here, a hafnium containing film represents an HfSiO₂ film (or HfSiO film); a zirconium containing film a ZrSiO₂ film (or a ZrSiO film); and a hafnium/zirconium containing film an (Hf, Zr) SiO₂ film (or an (Hf, Zr) SiO film). Further, nitrogen may also be contained in the dielectric film 32a and, in this case, it may be represented as an HfSiON film, a ZrSiON film and an (Hf, Zr) SiON film. With Nₛᵢ representing the number of atoms of silicon in the dielectric film 32a and Nₑₗ the number of atoms of said at least one element, it is desired that Nₛᵢ<Nₑₗ/². By the ratio of the number of atoms of the silicon it is possible to obtain a dielectric film having a high dielectric constant.

In an example shown in FIG. 2B, the dielectric region 32 comprises a dielectric film 32a and a dielectric film (second dielectric film) 32b formed on the electric film 32a and different from the dielectric film 32a. A lower surface of the dielectric film 32a is contacted with a lower electrode 31. It is desired that, as the dielectric film 32b, use be made of a dielectric material with higher relative dielectric constant than the dielectric film 32a, in particular, a dielectric material having a relative dielectric constant of 20 or more. For example, as the dielectric film 32b use can be made of a Ta₂O₅ film, an HfO₂ film, etc.

In an example shown in FIG. 2C, a dielectric region 32 comprises a dielectric film 32a and a dielectric film 32b formed beneath the dielectric film 32a. An upper surface of the dielectric film 32a is contacted with an upper electrode 33.

In an example shown in FIG. 2D, a dielectric region 32 comprises a dielectric film 32a, a dielectric film 32b and a dielectric film 32c (third dielectric film) formed in that order. The lower surface of the dielectric film 32a is contacted with the lower electrode 31 and the upper surface of the dielectric film 32c is contacted with an upper electrode 33. As the dielectric film 32c use can be made of a dielectric material the same as that of the above-mentioned dielectric film 32a.

In the above-mentioned example, use can be made, as the lower electrode 31 and upper electrode 33, of a conduction film having a metallic property (electroconductive film revealing a metallic conduction), for example, a metal nitride film (a TiN film, a WN film, a TaN film, etc.) or a stacked film of a metal nitride film and a metal film.

According to the present embodiment, therefore, as the dielectric film of a capacitor, use is made of a dielectric film containing silicon, oxygen and at least one element of hafnium and zirconium. By such a structure, the oxidation reduction reaction is suppressed at an interface between the dielectric film and the electrode and it is possible to reduce leakage current. It is also possible to reduce the voltage dependence and temperature dependence of the electric capacitance and suppress a variation in the electric capacitance. It is, therefore, possible to obtain a capacitor excellent in the characteristics and reliability. In the case where nitrogen is further contained in the dielectric film, it is possible to enhance the dielectric constant and to further reduce the leakage current because difficulty is encountered in crystallization. Through a combination with a dielectric film such as a Ta₂O₅ film, an HfO₂ film, it is possible to enhance the dielectric constant of a whole dielectric region and further improve the film formation speed throughout the dielectric region.

As the practical embodiments of the present invention, an explanation will be made below about the first to third embodiments of the present invention.

(First Embodiment)

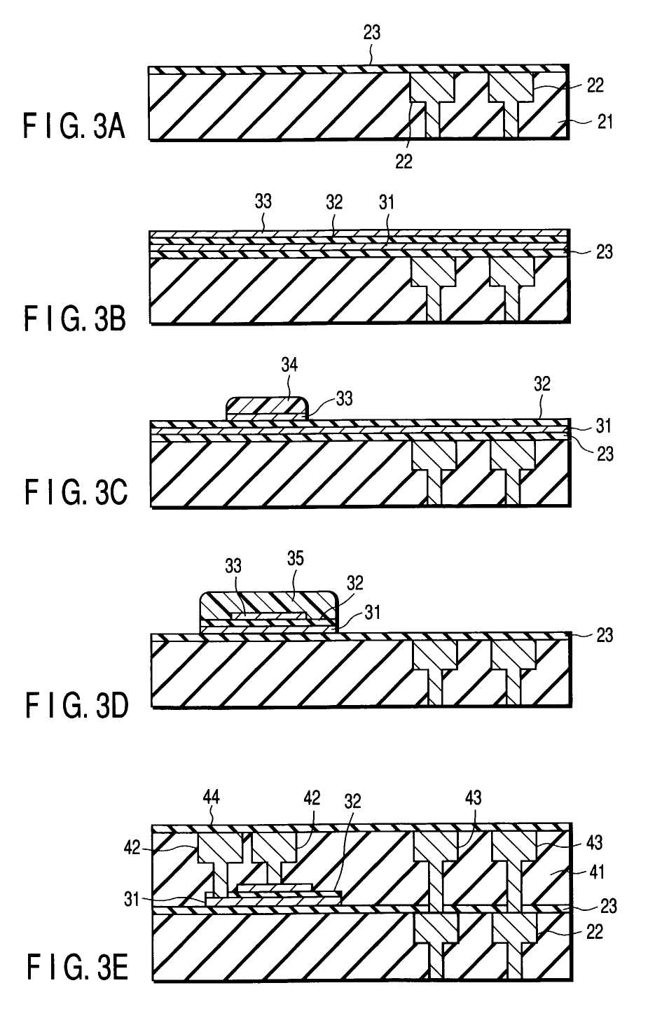

FIGS. 3A to 3E are cross-sectional views showing, as a model, a manufacturing process of a semiconductor device according to a first embodiment of the present invention.

As shown in FIG. 3A, through holes are formed in the interlayer insulating film 21 on a semiconductor substrate, not shown. A wiring may be initially formed in the interlayer insulating film 21. Then a Cu film is deposited on the whole surface, followed by a planarization process by a CMP. By doing so, Cu-film buried plugs 22 are formed in the through holes. Then an SiN film 23 is formed as an insulating film on the whole surface. By the SiN film 23 it is possible to prevent Cu diffusion in a later thermal treatment step.

Then, as shown in FIG. 3B, a TiN film is formed as a lower electrode film 31 by means of sputtering. Then a 50 nm-thick dielectric film (dielectric region) 32 is formed on the lower electrode film 31. In the present example, a sample was manufactured with an HfSiO₂ film and a sample was manufactured with an HfSiON film, as a dielectric film 32. The sample using the HfSiO₂ film was formed by sputtering under an oxygen containing atmosphere and the sample using the HfSiON film was formed by sputtering under an atmosphere containing oxygen and nitrogen. In either sample, use was made of a target which satisfies a number-of-atoms ratio of Hf:Si=8:2 The target contains 500 ppm of Zr and, from a formed film, Zr of the corresponding ratio was detected. Upon evaluation of the oxygen/nitrogen ratio by an Auger electron spectroscopy for the HfSiON film, the number-of-atoms ratio was O:N=8:2. Subsequently, a TiN film was formed, by sputtering, as an upper electrode film 33 on the dielectric film 32.

Then as shown in FIG. 3C, a photoresist film 34 is formed and, with the photoresist film 34 used as a mask, the upper electrode 33 is etched.

Then as shown in FIG. 3D, a photoresist film 35 is formed and, with the photoresist film 35 used as a mask, the dielectric film 32 and lower electrode film 31 are etched to form an MIM capacitor structure.

As shown in FIG. 3E, the MIM capacitor structure was covered with an interlayer insulating film 41 and, after forming through holes in the interlayer insulating film 41, a Cu film is deposited on a whole surface. Then a planarization process is performed by the CMP method, etc., to leave Cu-film-buried plugs 42 and 43 in the through holes. The plug 42 is connected to the electrode of the capacitor and the plug 43 is connected to the plug 22. Then an SiN film 44 is formed as an insulating film on a whole surface. By providing the SiN film 44 it is possible to prevent the Cu diffusion and also prevent a moisture intrusion from an outside.

By this process, a semiconductor device is obtained which has a capacitor comprised of a stacked structure of a lower electrode 31, a dielectric film 32 and an upper electrode 33.

The characteristic of the thus obtained capacitor was measured. As a result, for the sample using the HfSiO₂ film as the dielectric film 32, the leakage current was below 10⁻¹⁰ A/mm² (−3V to +3V), the electric capacitance was 4.0 fF/μm², the voltage variation of the electric capacitance was 70 ppm/V and the temperature variation of the electric capacitance at 25 to 85° C. was 90 ppm/° C. For the sample using the HfSiON as the dielectric film 32, the leakage current was below 10⁻¹⁰ A/mm² (−3V to +3V), the electric capacitance was 4.2 fF/μm², the voltage variation of the electric capacitance was 60 ppm/V, and the temperature variation of the electric capacitance at 25 to 85° C. was 80 ppm/° C. In comparison with the case of using the HfSiO₂ film it is possible to improve the dielectric constant in the case of using the HfSiON. Since N is added, it is hard to crystallize even if annealing is effected and it is effective to suppress the leakage current.

### COMPARATIVE EXAMPLE 1

As an comparative example, a sample was manufactured using an HfO₂ film as a dielectric film 32. The HfO₂ film was 50 nm thick and formed by sputtering using an Hf target. The structure was the same as the capacitor of the first embodiment except that an HfO₂ film was used as the dielectric film 32.

The capacitor was measured for its characteristics. The leakage current was below 10⁻¹⁰ A/mm² (−3V to +3V) and the electric capacitance was 4.5 fF/μm². However, a voltage variation of the electric capacitance was 250 ppm/V and a temperature variation of the electric capacitance at 25 to 85° C. was 200 ppm/° C. It has been found that the characteristics was greatly deteriorated in comparison with the present embodiment.

(Second Embodiment)

The present embodiment is of such a type that a dielectric region 32 of a capacitor is comprised of a stacked structure. This embodiment is the same in the basic structure and manufacturing process as the first embodiment except the dielectric region 32. The basic structure of the capacitor corresponds to that shown in FIG. 2D. That is, the structure corresponds to that in which an intermediate dielectric film is sandwiched between an upper dielectric film and a lower dielectric film.

Samples (A) to (D) were manufactured as upper and lower dielectric films of the dielectric region 32, the sample (A) using an HfSiO₂ film, the sample (B) using an HfSiON film, the sample (C) using a ZrSiO₂ film and the sample (D) using a ZrSiON film. These samples were formed by sputtering and the upper and lower dielectric films were 5 nm thick. For the samples (A) and (B), use was made of a target which satisfies a ratio of Hf:Si=8:2 while, for the samples (C) and (D), use was made of a target which satisfies a ratio of Zr:Si=6:4. In each sample, a Ta₂O₅ film was used as an intermediate dielectric film. The Ta₂O₅ film was 40 nm thick and formed by a sputtering method using a Ta target. Further, for each sample, the lower dielectric film, the intermediate dielectric film and the upper dielectric film were continuously formed without being exposed to an outer atmosphere. The relative dielectric constants of the HfSiO₂ film, the HfSiON film, the ZrSiO₂ film, the ZrSiON film and the Ta₂O₅ film are 18, 20, 16, 18 and 27, respectively.

For the respective manufacturing samples-samples (A) to (D), the capacitors were measured for their characters. As a result, it has been found that, for each sample, the leakage current was below 10⁻¹⁰ A/mm² (−3V to +3V). The electric capacitance was 4.0 fF/μm² for the sample (A), 4.2 fF/μm² for the sample (B), 3.7 fF/μm² for the sample (C), and 3.9 fF/μm² for the sample (D). The voltage variation of the electric capacitance was 100 ppm/V for the sample (A), 80 ppm/V for the sample (B), 60 ppm/V for the sample (C) and 40 ppm/V for the sample (D). The temperature variation of the electric capacitance at 25 to 85° C. was 80 ppm/° C. for the sample (A), 90 ppm/° C. for the sample (B), 45 ppm/° C. for the sample (C) and 38 ppm/° C. for the sample (D).

### COMPARATIVE EXAMPLE 2

As a comparative example, a sample was manufactured using only a Ta₂O₅ film as a dielectric region 32. The Ta₂O₅ film was 40 nm thick and formed by sputtering using a Ta target. The structure is the same as the capacitor of the first embodiment except that the Ta₂O₅ film was used as the dielectric region 32.

Upon the measurement of the capacitor for characteristics, the leakage current was about 10⁻⁸ A/mm² at ±3V, the voltage variation of the electric capacitance is 480 ppm/V and the temperature variation of the electric capacitance at 25 to 85° C. was 200 ppm/° C., thus revealing poor characteristics compared with those of the present embodiment.

(Third Embodiment)

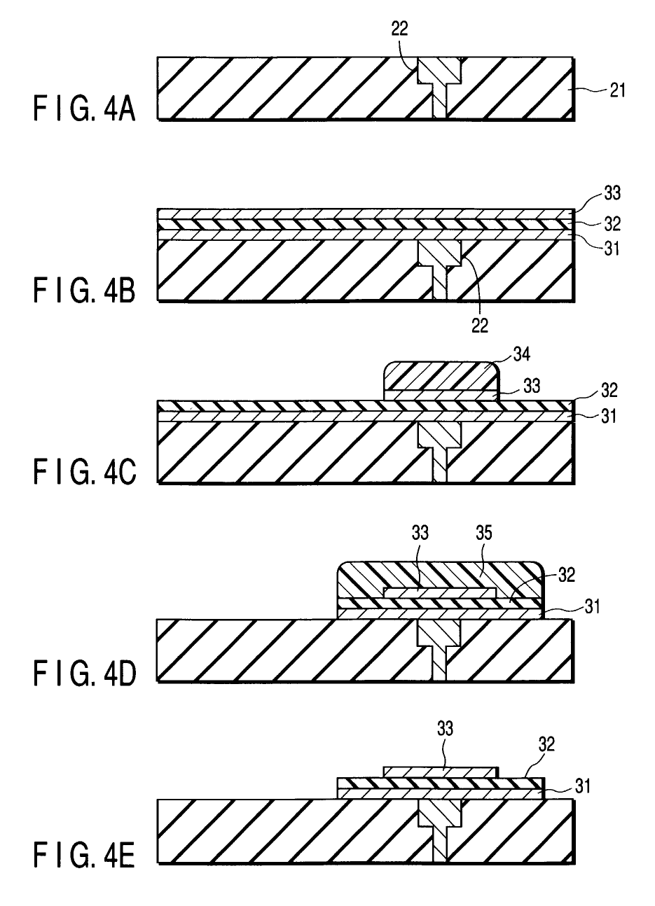

FIGS. 4A to 4E are cross-sectional views showing a model of a manufacturing process of a semiconductor device according to a third embodiment of the present invention.

First, as shown in FIG. 4A, a through hole is formed in an interlayer insulating film 21 on a semiconductor substrate (not shown). It may be possible to initially form a wiring in the interlayer insulating film 21. Subsequently, a W film is deposited on a whole surface, followed by a planarization process by the CMP method, etc. By doing so, a W film buried plug 22 is formed in the through hole.

Then, as shown in FIG. 4B, a stacked film including a TiN film, a Ti film and a TiN film are continuously formed by sputtering as a lower electrode film 31. Then, a dielectric film (dielectric region) 32 is formed by the following way on the lower electrode film 31. First, an organic solvent (Hf:Si=5:1) using Hf(OBu)₄ and Si(OEt)₄ is spin coated on the lower electrode film 31. Then UV-03 process is performed using light of an excitation wavelength of 172 nm under the presence Of O₂. After this, a heat treatment is performed at 400° C. in an oxygen atmosphere to provide an 8 nm thick HfSiO₂ film. The spin coating step, the UV-03 step and the heat treatment step are repeated three times to provide a dielectric film (HfSiO₂ film) 32 having a whole thickness of 24 nm. The HfSiO₂ film was found to be amorphous upon being confirmed by an X-ray diffraction for its crystallinity. Subsequently, a stacked film of a TiN film/Ti film/TiN film structure is formed by sputtering in a continuous process.

Then as shown in FIG. 4C, a photoresist film 34 is formed and, with a photoresist film 34 used as a mask, the upper electrode film 33 is etched.

A photoresist film 35 is formed as shown in FIG. 4D and, with the photoresist film 35 used as a mask, a dielectric film 32 and a lower electrode film 31 are etched.

Then as shown in FIG. 4E, a photoresist film 35 is removed to provide an MIM capacitor structure in which the lower electrode 31, the dielectric film 32 and the upper electrode 33 are stacked. A subsequent process, though being not shown, includes an MIM capacitor structure-covering interlayer insulating step forming step, a through hole forming step, a “burring of an Al plug in the through hole” forming step, etc.

Upon measuring the thus obtained capacitor for its characteristics, the leakage current was below 10⁻¹⁰ A/mm² (−3V to +3V), the electric capacitance was 7.0 fF/μm², the voltage variation of an electric capacitance was 80 ppm/V, and the temperature variation of the electric capacitance at 25 to 85° C. was 100 ppm/° C. Even if a coating film is used as a dielectric film of a capacitor, a capacitor of excellent characteristics can be obtained as in the cases of the first and second embodiments.

Further, a sample having a varying ratio (Hf:Si) of Hf and Si in a source of the coated film (an organic solvent using Hf(OBu)₄ and Si(OEt)₄) was manufactured. An amount of Si was relatively increased and a drop in the dielectric constant of a dielectric film occurred. In a sample of a ratio of Hf:Si=5:5, the relative dielectric constant was below 10. It is desired that, in order to obtain a dielectric film having a dielectric constant exceeding a certain extent, a ratio of the number of Si atoms in the dielectric film be made to a certain small extent.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device, comprising:
a semiconductor substrate; and
a capacitor provided above the semiconductor substrate and comprising a lower electrode having a metallic property, an upper electrode having a metallic property and a dielectric region provided between the lower electrode and the upper electrode, the dielectric region including a first dielectric film containing silicon, oxygen and at least one element selected from hafnium and zirconium.

2. The semiconductor device according to claim 1, wherein the first dielectric film further contains nitrogen.

3. The semiconductor device according to claim 1, wherein the dielectric region further includes a second dielectric film provided between the upper electrode and the first dielectric film or between the lower electrode and the first dielectric film and different from the first dielectric film.

4. The semiconductor device according to claim 1, wherein the dielectric region further includes a second dielectric film provided between the upper electrode and the first dielectric film and different from the first dielectric film and a third dielectric film provided between the upper electrode and the second dielectric film and containing silicon, oxygen and at least one element selected from hafnium and zirconium.

5. The semiconductor device according to claim 3, wherein a dielectric constant of the second dielectric film is higher than that of the first dielectric film.

6. The semiconductor device according to claim 4, wherein a dielectric constant of the second dielectric film is higher than that of the first and third dielectric films.

7. The semiconductor device according to claim 3, wherein a relative dielectric constant of the second dielectric film is not lower than 20.

8. The semiconductor device according to claim 4, wherein a relative dielectric constant of the second dielectric film is not lower than 20.

9. The semiconductor device according to claim 1, wherein at least one of the lower electrode and the upper electrode includes a metal nitride film.

10. The semiconductor device according to claim 1, wherein the number of Si atoms in the first dielectric film is smaller than 1/2 the number of atoms of said at least one element in the first dielectric film.

11. The semiconductor device according to claim 1, wherein the first dielectric film is formed of a coated film.
